(19) United States
(12) Patent Application Publication
(10) Pub. No.: US 2012/0225192 A1
(43) Pub. Date: Sep. 6, 2012

(54) Apparatus And Process For Atomic Layer Deposition

(75) Inventors: Joseph Yudovsky, Campbell, CA (US); Garry K. Kwong, San Jose, CA (US); Mei Chang, Saratoga, CA (US); Anh N. Nguyen, Milpitas, CA (US); David Thompson, San Jose, CA (US)

(73) Assignee: Applied Materials, Inc., Santa Clara, CA (US)

(21) Appl. No.: 13/189,692

(22) Filed: Jul. 25, 2011

Related U.S. Application Data
(63) Continuation of application No. 13/037,992, filed on Mar. 1, 2011.

(51) Int. Cl. C23C 16/458; B05D 5/12

(52) U.S. Cl. 427/58; 118/719

(57) ABSTRACT

Provided are atomic layer deposition apparatus and methods including a gas distribution plate comprising at least one gas injector unit. Each gas injector unit comprises a plurality of elongate gas injectors including at least two first reactive gas injectors and at least one second reactive gas injector, the at least two first reactive gas injectors surrounding the at least one second reactive gas injector. Also provided are atomic layer deposition apparatuses and methods including a gas distribution plate with a plurality of gas injector units.

### STATEMENT OF RELATED CASES

This application is a continuation of U.S. patent application Ser. No. 13/037,992, filed Mar. 1, 2011, which is incorporated herein by reference.

### BACKGROUND

Embodiments of the invention generally relate to an apparatus and a method for depositing materials. More specifically, embodiments of the invention are directed to a atomic layer deposition chambers with linear reciprocal motion.

In the field of semiconductor processing, flat-panel display processing or other electronic device processing, vapor deposition processes have played an important role in depositing materials on substrates. As the geometries of electronic devices continue to shrink and the density of devices continues to increase, the size and aspect ratio of the features are becoming more aggressive, e.g., feature sizes of 0.07 μm and aspect ratios of 10 or greater. Accordingly, conformal deposition of materials to form these devices is becoming increasingly important.

During an atomic layer deposition (ALD) process, reactant gases are introduced into a process chamber containing a substrate. Generally, a first reactant is introduced into a process chamber and is adsorbed onto the substrate surface. A second reactant is introduced into the process chamber and reacts with the first reactant to form a deposited material. A purge step may be carried out to ensure that the only reactions that occur are on the substrate surface. The purge step may be a continuous purge with a carrier gas or a pulse purge between the delivery of the reactant gases.

There is an ongoing need in the art for improved apparatuses and methods for processing substrates by atomic layer deposition.

### SUMMARY

Embodiments of the invention are directed to atomic layer deposition systems comprising a processing chamber. A gas distribution plate is in the processing chamber. The gas distribution plate comprises at least one gas injector unit. Each gas injector unit comprises a plurality of elongate gas injectors including at least two first reactive gas injectors in fluid communication with a first reactive gas and at least one second reactive gas injector in fluid communication with a second reactive gas different from the first reactive gas. The at least two first reactive gas injectors surrounding the at least one second reactive gas injector. A substrate carrier is configured to move a substrate reciprocally with respect to the gas injector unit in a back and forth motion perpendicular to an axis of the elongate gas injectors. In specific embodiments, the substrate carrier is configured to rotate the substrate.

In detailed embodiments, the plurality of gas injectors further comprises at least one third gas injector, the at least two first gas injectors surrounding the at least one third gas injector.

In some embodiments, the at least one gas injector unit further comprises at least two purge gas injectors, each of the purge gas injectors between the at least one first gas injector and the at least one second gas injector. In detailed embodiments, the at least one gas injector unit further comprises at least four vacuum ports, each of the vacuum ports disposed between each of the at least one first reactive gas injector, the at least one second reactive gas injector and the at least two purge gas injectors.

In some embodiments, the gas distribution plate has one gas injector unit. The gas injector unit consists essentially of, in order, a leading first reactive gas injector, a second reactive gas injector and a trailing first reactive gas injector. In detailed embodiments, the gas distribution plate further comprises a purge gas injector between the leading first reactive gas injector and the second reactive gas injector, and a purge gas injector between the second reactive gas injector and the trailing first reactive gas injector, each purge gas injector separated from the reactive gas injectors by a vacuum. In specific embodiments, the gas distribution plate further comprises, in order, a vacuum port, a purge gas injector and another vacuum port before the leading first reactive gas injector and after the second first reactive gas injector. In particular embodiments, the gas distribution plate further comprises a first vacuum channel and a second vacuum channel, the first vacuum channel in flow communication with vacuum ports adjacent the first reactive gas injectors and the second vacuum channel in flow communication with vacuum ports adjacent the second reactive gas injector.

In some embodiments, the at least one gas injector unit further comprises at least two vacuum ports disposed between the at least one first reactive gas injector and the at least one second reactive gas injector.

In one or more embodiments, the substrate carrier is configured to transport the substrate from a region in front of the gas distribution plate to a region after the gas distribution plate so that the entire substrate surface passes through a region occupied by the gas distribution plate.

According to some embodiments, there are in the range of 2 to 24 gas injectors units. In detailed embodiments, each of the gas injectors consists essentially of, in order, a leading first reactive gas injector, a second reactive gas injector, and a trailing first reactive gas injector. In specific embodiments, the system further comprises a substrate carrier configured to carry a substrate and to move, during processing, in a linear reciprocal path between a first extent and second extent, wherein a distance between the first extent and the second extent is about equal to a length of the substrate divided by the number of gas injector units. In particular embodiments, the substrate carrier is configured to carry the substrate outside of the first extent to a loading position.

Additional embodiments of the invention are directed to atomic layer deposition systems comprising a processing chamber. A gas distribution plate is in the processing chamber. The gas distribution plate comprises a plurality of gas injectors. The plurality of gas injectors consists essentially of, in order, a vacuum port, a purge gas injector in flow communication with a purge gas, a vacuum port, a first reactive gas injector in flow communication with a first reactive gas, a vacuum port, a purge gas injector in flow communication with the purge gas, a vacuum port, a second reactive gas injector in flow communication with a second reactive gas different from the first reactive gas, a vacuum port, a purge gas injector in flow communication with the purge gas, a vacuum port, a first reactive gas injector in flow communication with the first reactive gas, a vacuum port, a purge gas injector in flow communication with the purge gas and a vacuum port. A substrate carrier is configured to move a substrate reciprocally with respect to the gas distribution plate in a back and forth motion along an axis perpendicular to an axis of the elongate gas injectors.

Further embodiments of the invention are directed to methods of processing a substrate. A portion of a substrate is passed across a gas injector unit in a first direction so that the portion of the substrate is exposed to, in order, a leading first reactive gas stream, a second reactive gas stream different from the first reactive gas stream and a trailing first reactive gas stream to deposit a first layer. The portion of the substrate I passed across the gas injector unit in a second gas direction opposite of the first direction so that the portion of the substrate is exposed to, in order, the trailing first reactive gas stream, the second reactive gas stream and the leading first reactive gas stream to create a second layer.

In some embodiments, the portion of the substrate is further exposed to a purge gas stream between each of the first reactive gas streams and the second reactive gas streams. In detailed embodiments, passing the portion of the substrate in a first direction exposes the portion of the substrate to, in order, a leading first reactive gas stream, a leading second reactive gas stream, a first intermediate first reactive gas stream, a third reactive gas stream, a second intermediate first reactive gas stream, a trailing second reactive gas stream and a trailing first reactive gas stream, and passing the portion of the substrate in the second direction exposes the portion of the substrate to the gas streams in reverse order. In specific embodiments, the substrate is divided into a plurality of portions in the range of about 2 to about 24, and each individual portion is exposed to the gas streams substantially simultaneously.

### BRIEF DESCRIPTION OF THE DRAWINGS

So that the manner in which the above recited features of the invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a schematic side view of an atomic layer deposition chamber according to one or more embodiments of the invention;

FIG. 2 shows a susceptor in accordance with one or more embodiments of the invention;

FIG. 3 show a partial perspective view of an atomic layer deposition chamber in accordance with one or more embodiments of the invention;

FIGS. 4A and 4B show a views of a gas distribution plate in accordance with one or more embodiments of the invention;

FIG. 5 shows a schematic cross-sectional view of a gas distribution plate in accordance with one or more embodiments of the invention;

FIG. 6 shows a schematic cross-sectional view of a gas distribution plate in accordance with one or more embodiments of the invention;

FIG. 7 shows a schematic cross-sectional view of a gas distribution plate in accordance with one or more embodiments of the invention;

FIG. 8 shows a schematic cross-sectional view of a gas distribution plate in accordance with one or more embodiments of the invention;

FIG. 9 shows a schematic cross-sectional view of a gas distribution plate in accordance with one or more embodiments of the invention;

FIG. 10 shows a schematic cross-sectional view of a gas distribution plate in accordance with one or more embodiments of the invention;

FIG. 11 shows a schematic cross-sectional view of a gas distribution plate in accordance with one or more embodiments of the invention;

FIG. 12 shows a schematic cross-sectional view of a gas distribution plate in accordance with one or more embodiments of the invention;

FIG. 13 shows a schematic cross-sectional view of a gas distribution plate in accordance with one or more embodiments of the invention;

FIG. 14 shows a partial top view of a processing chamber in accordance with one or more embodiments of the invention;

FIGS. 15A and 15B show schematic views of a gas distribution plate in accordance with one or more embodiments of the invention; and

FIG. 16 shows a cluster tool in accordance with one or more embodiment of the invention.

### DETAILED DESCRIPTION

Embodiments of the invention are directed to atomic layer deposition apparatus and methods which provide improved movement of substrates. Specific embodiments of the invention are directed to atomic layer deposition apparatuses (also called cyclical deposition) incorporating a gas distribution plate having a detailed configuration and reciprocal linear motion.

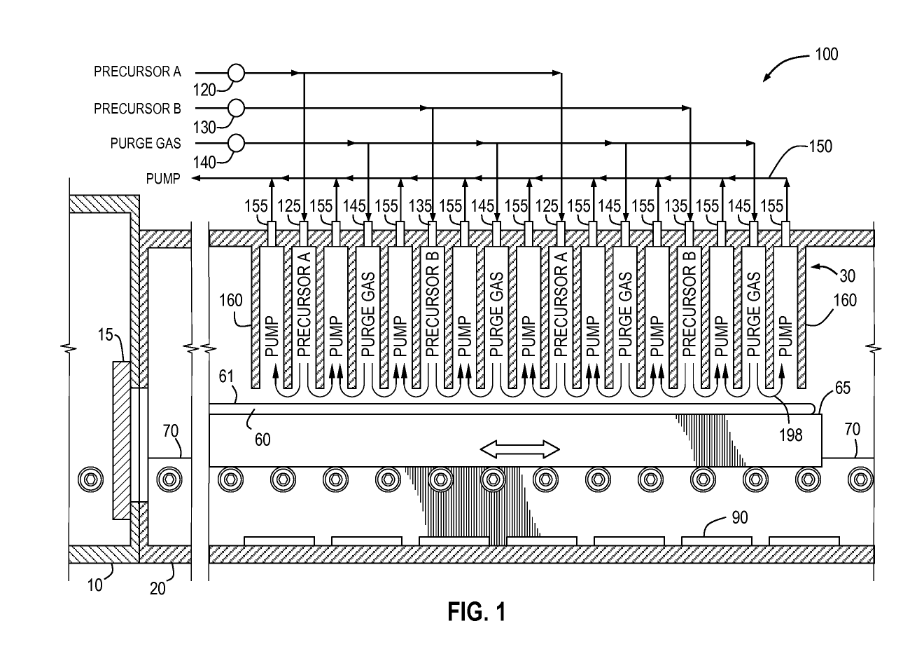

FIG. 1 is a schematic cross-sectional view of an atomic layer deposition system 100 or reactor in accordance with one or more embodiments of the invention. The system 100 includes a load lock chamber 10 and a processing chamber 20. The processing chamber 20 is generally a sealable enclosure, which is operated under vacuum, or at least low pressure. The processing chamber 20 is isolated from the load lock chamber 10 by an isolation valve 15. The isolation valve 15 seals the processing chamber 20 from the load lock chamber 10 in a closed position and allows a substrate 60 to be transferred from the load lock chamber 10 through the valve to the processing chamber 20 and vice versa in an open position.

The system 100 includes a gas distribution plate 30 capable of distributing one or more gases across a substrate 60. The gas distribution plate 30 can be any suitable distribution plate known to those skilled in the art, and specific gas distribution plates described should not be taken as limiting the scope of the invention. The output face of the gas distribution plate 30 faces the first surface 61 of the substrate 60.

Substrates for use with the embodiments of the invention can be any suitable substrate. In detailed embodiments, the substrate is a rigid, discrete, generally planar substrate. As used in this specification and the appended claims, the term “discrete” when referring to a substrate means that the substrate has a fixed dimension. The substrate of specific embodiments is a semiconductor wafer, such as a 200 mm or 300 mm diameter silicon wafer.

The gas distribution plate 30 comprises a plurality of gas ports configured to transmit one or more gas streams to the substrate 60 and a plurality of vacuum ports disposed between each gas port and configured to transmit the gas streams out of the processing chamber 20. In the detailed embodiment of FIG. 1, the gas distribution plate 30 comprises a first precursor injector 120, a second precursor injector 130 and a purge gas injector 140. The injectors 120, 130, 140 may be controlled by a system computer (not shown), such as a mainframe, or by a chamber-specific controller, such as a programmable logic controller. The precursor injector 120 is configured to inject a continuous (or pulse) stream of a reactive precursor of compound A into the processing chamber 20 through a plurality of gas ports 125. The precursor injector 130 is configured to inject a continuous (or pulse) stream of a reactive precursor of compound B into the processing chamber 20 through a plurality of gas ports 135. The purge gas injector 140 is configured to inject a continuous (or pulse) stream of a non-reactive or purge gas into the processing chamber 20 through a plurality of gas ports 145. The purge gas is configured to remove reactive material and reactive by-products from the processing chamber 20. The purge gas is typically an inert gas, such as, nitrogen, argon and helium. Gas ports 145 are disposed in between gas ports 125 and gas ports 135 so as to separate the precursor of compound A from the precursor of compound B, thereby avoiding cross-contamination between the precursors.

In another aspect, a remote plasma source (not shown) may be connected to the precursor injector 120 and the precursor injector 130 prior to injecting the precursors into the chamber 20. The plasma of reactive species may be generated by applying an electric field to a compound within the remote plasma source. Any power source that is capable of activating the intended compounds may be used. For example, power sources using DC, radio frequency (RF), and microwave (MW) based discharge techniques may be used. If an RF power source is used, it can be either capacitively or inductively coupled. The activation may also be generated by a thermally based technique, a gas breakdown technique, a high intensity light source (e.g., UV energy), or exposure to an x-ray source. Exemplary remote plasma sources are available from vendors such as MKS Instruments, Inc. and Advanced Energy Industries, Inc.

The system 100 further includes a pumping system 150 connected to the processing chamber 20. The pumping system 150 is generally configured to evacuate the gas streams out of the processing chamber 20 through one or more vacuum ports 155. The vacuum ports 155 are disposed between each gas port so as to evacuate the gas streams out of the processing chamber 20 after the gas streams react with the substrate surface and to further limit cross-contamination between the precursors.

The system 100 includes a plurality of partitions 160 disposed on the processing chamber 20 between each port. A lower portion of each partition extends close to the first surface 61 of substrate 60, for example about 0.5 mm from the first surface 61, This distance should be such that the lower portions of the partitions 160 are separated from the substrate surface by a distance sufficient to allow the gas streams to flow around the lower portions toward the vacuum ports 155 after the gas streams react with the substrate surface. Arrows 198 indicate the direction of the gas streams. Since the partitions 160 operate as a physical barrier to the gas streams, they also limit cross-contamination between the precursors. The arrangement shown is merely illustrative and should not be taken as limiting the scope of the invention. It will be understood by those skilled in the art that the gas distribution system shown is merely one possible distribution system and the other types of showerheads and gas distribution systems may be employed.

In operation, a substrate 60 is delivered (e.g., by a robot) to the load lock chamber 10 and is placed on a carrier 65. After the isolation valve 15 is opened, the carrier 65 is moved along the track 70, which may be a rail or frame system. Once the carrier 65 enters in the processing chamber 20, the isolation valve 15 closes, sealing the processing chamber 20. The carrier 65 is then moved through the processing chamber 20 for processing. In one embodiment, the carrier 65 is moved in a linear path through the chamber.

As the substrate 60 moves through the processing chamber 20, the first surface 61 of substrate 60 is repeatedly exposed to the precursor of compound A coming from gas ports 125 and the precursor of compound B coming from gas ports 135, with the purge gas coming from gas ports 145 in between. Injection of the purge gas is designed to remove unreacted material from the previous precursor prior to exposing the substrate surface 110 to the next precursor. After each exposure to the various gas streams (e.g., the precursors or the purge gas), the gas streams are evacuated through the vacuum ports 155 by the pumping system 150. Since a vacuum port may be disposed on both sides of each gas port, the gas streams are evacuated through the vacuum ports 155 on both sides. Thus, the gas streams flow from the respective gas ports vertically downward toward the first surface 61 of the substrate 60, across the first surface 110 and around the lower portions of the partitions 160, and finally upward toward the vacuum ports 155. In this manner, each gas may be uniformly distributed across the substrate surface 110. Arrows 198 indicate the direction of the gas flow. Substrate 60 may also be rotated while being exposed to the various gas streams. Rotation of the substrate may be useful in preventing the formation of strips in the formed layers. Rotation of the substrate can be continuous or in discrete steps.

Sufficient space is generally provided at the end of the processing chamber 20 so as to ensure complete exposure by the last gas port in the processing chamber 20. Once the substrate 60 reaches the end of the processing chamber 20 (i.e., the first surface 61 has completely been exposed to every gas port in the chamber 20), the substrate 60 returns back in a direction toward the load lock chamber 10. As the substrate 60 moves back toward the load lock chamber 10, the substrate surface may be exposed again to the precursor of compound A, the purge gas, and the precursor of compound B, in reverse order from the first exposure.

The extent to which the substrate surface 110 is exposed to each gas may be determined by, for example, the flow rates of each gas coming out of the gas port and the rate of movement of the substrate 60. In one embodiment, the flow rates of each gas are configured so as not to remove adsorbed precursors from the substrate surface 110. The width between each partition, the number of gas ports disposed on the processing chamber 20, and the number of times the substrate is passed back and forth may also determine the extent to which the substrate surface 110 is exposed to the various gases. Consequently, the quantity and quality of a deposited film may be optimized by varying the above-referenced factors.

In another embodiment, the system 100 may include a precursor injector 120 and a precursor injector 130, without a purge gas injector 140. Consequently, as the substrate 60 moves through the processing chamber 20, the substrate surface 110 will be alternately exposed to the precursor of compound A and the precursor of compound B, without being exposed to purge gas in between.

The embodiment shown in FIG. 1 has the gas distribution plate 30 above the substrate. While the embodiments have been described and shown with respect to this upright orientation, it will be understood that the inverted orientation is also possible. In that situation, the first surface 61 of the substrate 60 will face downward, while the gas flows toward the substrate will be directed upward.

In yet another embodiment, the system 100 may be configured to process a plurality of substrates. In such an embodiment, the system 100 may include a second load lock chamber (disposed at an opposite end of the load lock chamber 10) and a plurality of substrates 60. The substrates 60 may be delivered to the load lock chamber 10 and retrieved from the second load lock chamber.

In one or more embodiments, at least one radiant heat lamps 90 is positioned to heat the second side of the substrate. The radiant heat source is generally positioned on the opposite side of gas distribution plate 30 from the substrate. In these embodiments, the gas cushion plate is made from a material which allows transmission of at least some of the light from the radiant heat source. For example, the gas cushion plate can be made from quartz, allowing radiant energy from a visible light source to pass through the plate and contact the back side of the substrate and cause an increase in the temperature of the substrate.

In some embodiments, the carrier 65 is a susceptor 66 for carrying the substrate 60. Generally, the susceptor 66 is a carrier which helps to form a uniform temperature across the substrate. The susceptor 66 is movable in both directions (left-to-right and right-to-left, relative to the arrangement of FIG. 1) between the load lock chamber 10 and the processing chamber 20. The susceptor 66 has a top surface 67 for carrying the substrate 60. The susceptor 66 may be a heated susceptor so that the substrate 60 may be heated for processing. As an example, the susceptor 66 may be heated by radiant heat lamps 90, a heating plate, resistive coils, or other heating devices, disposed underneath the susceptor 66.

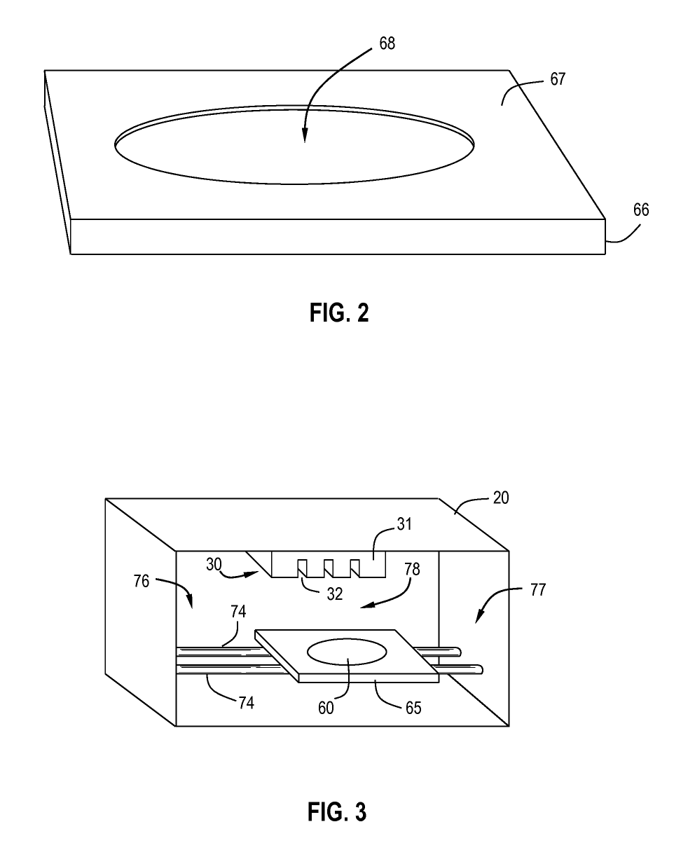

In still another embodiment, the top surface 67 of the susceptor 66 includes a recess 68 configured to accept the substrate 60, as shown in FIG. 2. The susceptor 66 is generally thicker than the thickness of the substrate so that there is susceptor material beneath the substrate. In detailed embodiments, the recess 68 is configured such that when the substrate 60 is disposed inside the recess 68, the first surface 61 of substrate 60 is level with the top surface 67 of the susceptor 66. Stated differently, the recess 68 of some embodiments is configured such that when a substrate 60 is disposed therein, the first surface 61 of the substrate 60 does not protrude above the top surface 67 of the susceptor 66.

FIG. 3 shows a partial cross-sectional view of a processing chamber 20 in accordance with one or more embodiments of the invention. The processing chamber 20 has a gas distribution plate 30 with at least one gas injector unit 31. As used in this specification and the appended claims, the term “gas injector unit” is used to describe a sequence of gas outlets in a gas distribution plate 30 which are capable of depositing a discrete film on a substrate surface. For example, if a discrete film is deposited by combination of two components, then a single gas injector unit would include outlets for at least those two components. A gas injector unit 31 can also include any purge gas ports or vacuum ports within and around the gas outlets capable of depositing a discrete film. This is explained in detail below with respect to FIG. 9. The gas distribution plate 30 shown in FIG. 1 is made up of a single gas injector unit 31, but it should be understood that more than one gas injector unit 31 could be part of the gas distribution plate 30.

In some embodiments, the processing chamber 20 includes a substrate carrier 65 which is configured to move a substrate along a linear reciprocal path along an axis perpendicular to the elongate gas injectors. As used in this specification and the appended claims, the term “linear reciprocal path” refers to either a straight or slightly curved path in which the substrate can be moved back and forth. Stated differently, the substrate carrier may be configured to move a substrate reciprocally with respect to the gas injector unit in a back and forth motion perpendicular to the axis of the elongate gas injectors. As shown in FIG. 3, the carrier 65 is supported on rails 74 which are capable of moving the carrier 65 reciprocally from left-to-right and right-to-left, or capable of supporting the carrier 65 during movement. Movement can be accomplished by many mechanisms known to those skilled in the art. For example, a stepper motor may drive one of the rails, which in turn can interact with the carrier 65, to result in reciprocal motion of the substrate 60. In detailed embodiments, the substrate carrier is configured to move a substrate 60 along a linear reciprocal path along an axis perpendicular to and beneath the elongate gas injectors 32. In specific embodiments, the substrate carrier 65 is configured to transport the substrate 60 from a region 76 in front of the gas distribution plate 30 to a region 77 after the gas distribution plate 30 so that the entire substrate 60 surface passes through a region 78 occupied by the gas distribution plate

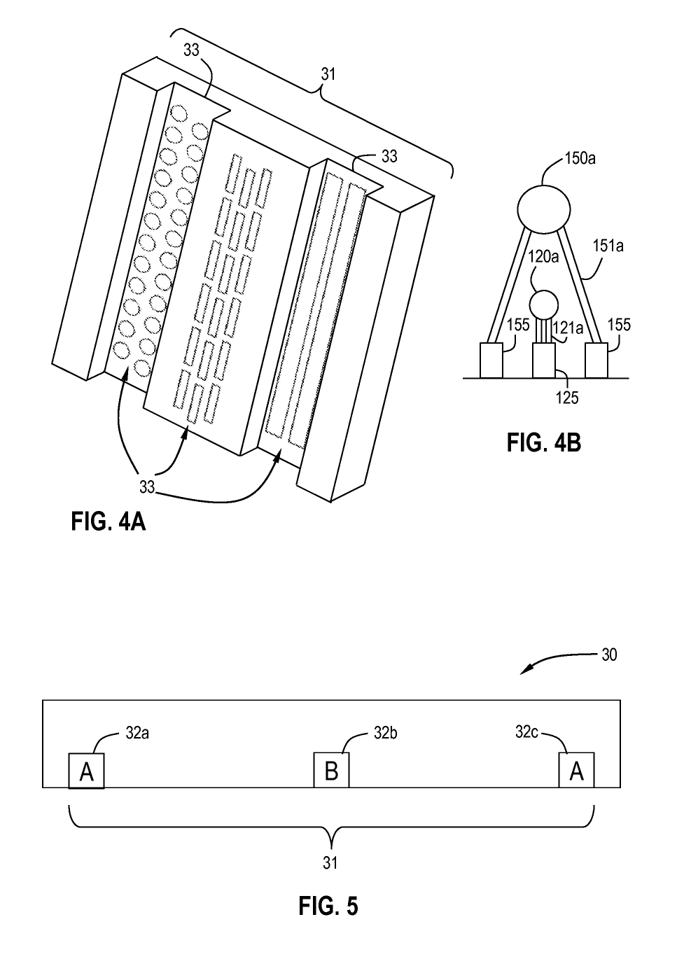

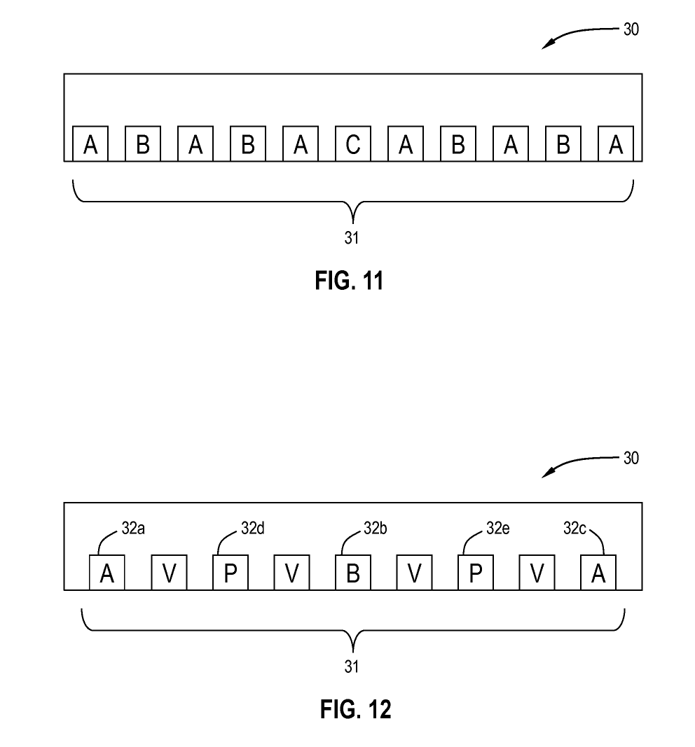

FIG. 4A shows a bottom perspective view of a gas distribution plate 30 in accordance with one or more embodiments of the invention. With reference to both FIGS. 3 and 4, each gas injector unit 31 comprises a plurality of elongate gas injectors 32. The elongate gas injectors 32 can be in any suitable shape or configuration with examples shown in FIG. 4A. The elongate gas injector 32 on the left of the drawing is a series of closely spaced holes. These holes are located at the bottom of a trench 33 formed in the face of the gas distribution plate 30. The trench 33 is shown extending to the ends of the gas distribution plate 30, but it will be understood that this is merely for illustration purposes and the trench does not need to extend to the edge. The elongate gas injector 32 in the middle is a series of closely spaced rectangular openings. This injector is shown directly on the face of the gas distribution plate 30 as opposed to being located within a trench 33. The trench of detailed embodiments has about 8 mm deep and has a width of about 10 mm. The elongate gas injector 32 on the right of FIG. 4A is shown as two elongate channels. FIG. 4B shows a side view of a portion of the gas distribution plate 30. A larger portion and description is included in FIG. 11. FIG. 4B shows the relationship of a single pumping plenum 150a with the vacuum ports 155. The pumping plenum 150a is connected to these vacuum ports 155 through two channels 151a. These channels 151 are in flow communication with the vacuum ports 155 by the elongate injectors 32 shown in FIG. 4A. In specific embodiments, the elongate injectors 32 have about 28 holes having a diameter of about 4.5 mm. In various embodiments, the elongate injectors 32 have in the range of about 10 to about 100 holes, or in the range of about 15 to about 75 holes, or in the range of about 20 to about 50 holes, or greater than 10 holes, 20 holes, 30 holes, 40 holes, 50 holes, 60 holes, 70 holes, 80 holes, 90 holes or 100 holes. In an assortment of embodiments, the holes have a diameter in the range of about 1 mm to about 10 mm, or in the range of about 2 mm to about 9 mm, or in the range of about 3 mm to about 8 mm, or in the range of about 4 mm to about 7 mm, or in the range of about 5 mm to about 6 mm, or greater than 1 mm, 2 mm, 3 mm, 4 mm, 5 mm, 6 mm, 7 mm, 8 mm, 9 mm or 10 mm. The holes can be lined up in two or more rows, scattered or evenly distributed, or in a single row. The gas supply plenum 120a is connected to the elongate gas injector 32 by two channels 121a. In detailed embodiments, the gas supply plenum 120a has a diameter of about 14 mm. In various embodiments, the gas supply plenum has a diameter in the range of about 8 mm to about 20 mm, or int eh range of about 9 mm to about 19 mm, or in the range of about 10 mm to about 18 mm, or in the range of about 11 mm to about 17 mm, or in the range of about 12 mm to about 16 mm, or in the range of about 13 mm to about 15 mm, or greater than 4 mm, 5 mm, 6 mm, 7 mm, 8 mm, 9 mm, 10 mm, 11 mm, 12 mm, 13 mm, 14 mm, 15 mm, 16 mm, 17 mm, 18 mm, 19 mm or 20 mm. In specific embodiments, these channels (from the plenums) have a diameter about 0.5 mm and there are about 121 of these channels in two rows, either staggered or evenly spaced. In various embodiments, the diameter is in the range of about 0.1 mm to about 1 mm, or in the range of about 0.2 mm to about 0.9 mm, or in the range of about 0.3 mm to about 0.8 mm or in the range of about 0.4 mm to about 0.7 mm, or greater than 0.2 mm, 0.3 mm, 0.4 mm, 0.5 mm, 0.6 mm, 0.7 mm, 0.8 mm, 0.9 mm or 1 mm. Although the gas supply plenum 120a is associated numerically with the first precursor gas, it will be understood that similar configurations may be made for the second reactive gases and the purge gases. Without being bound by any particular theory of operation, it is believed that the dimensions of the plenums, channels and holes define the conductance of the channels and uniformity.

FIGS. 5-13 show side, partial cross-sectional views of gas distribution plates 30 in accordance with various embodiments of the invention. The letters used in these drawings represent some of the different gases which may be used in the system. As a reference, A is a first reactive gas, B is a second reactive gas, C is a third reactive gas, P is a purge gas and V is vacuum. As used in this specification and the appended claims, the term “reactive gas” refers to any gas which may react with either the substrate, a film or partial film on the substrate surface. Non-limiting examples of reactive gases include hafnium precursors, water, cerium precursors, peroxide, titanium precursors, ozone, plasmas, Groups III-V elements. Purge gases are any gas which is non-reactive with the species or surface it comes into contact with. Non-limiting examples of purge gases include argon, nitrogen and helium. The reactive gas injectors on either end of the gas distribution plate 30 are the same so that the first and last reactive gas seen by a substrate passing the gas distribution plate 30 is the same. For example, if the first reactive gas is A, then the last reactive gas will also be A. If gas A and B are switched, then the first and last gas seen by the substrate will be gas B.

Referring to FIG. 5, the gas injector unit 31 of some embodiments comprises a plurality of elongate gas injectors including at least two first reactive gas injectors A and at least one second reactive gas injector B which is a different gas than that of the first reactive gas injectors. The first reactive gas injectors A are in fluid communication with a first reactive gas, and the second reactive gas injectors B are in fluid communication with a second reactive gas which is different from the first reactive gas. The at least two first reactive gas injectors A surround the at least one second reactive gas injector B so that a substrate moving from left-to-right will see, in order, the leading first reactive gas A, the second reactive gas B and the trailing first reactive gas A, resulting in a full layer being formed on the substrate. A substrate returning along the same path will see the opposite order of reactive gases, resulting in two layers for each full cycle. As a useful abbreviation, this configuration may be referred to at an ABA injector configuration. A substrate moved back and forth across this gas injector unit 31 would see a pulse sequence of
AB AAB AAB (AAB)ₙ . . . AABA
   forming a uniform film composition of B. Exposure to the first reactive gas A at the end of the sequence is not important as there is no follow-up by a second reactive gas B. It will be understood by those skilled in the art that while the film composition is referred to as B, it is really a product of the surface reaction products of reactive gas A and reactive gas B and that use of just B is for convenience in describing the films.

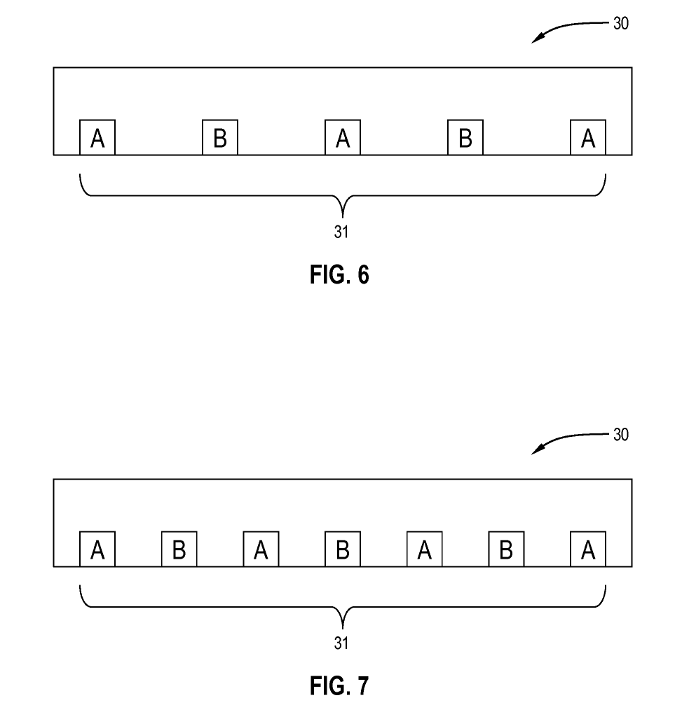

FIG. 6 shows another embodiment similar to that of FIG. 5 in which there are two second reactive gas B injectors, each surrounded by a first reactive gas A injector. A substrate moved back and forth across this gas injector unit 31 would see a pulse sequence of
ABAB AABAB (AABAB)ₙ . . . AABABA
   forming a uniform film composition of B. The main difference between the embodiment of FIG. 6 and FIG. 5 is that each full cycle (one back and forth movement) will result in four layers.

Similarly, FIG. 7 shows another embodiment of the injector unit 31 in which there are three second reactive gas B injectors, each surrounded by first reactive gas A injectors. A substrate moved back and forth across this gas injector unit 31 would see a pulse sequence of
ABABAB AABABAB (AABABAB)n . . . AABABABA
   resulting in the formation of a uniform film composition of B. A full cycle across this gas injector unit 31 would result in the formation of six layers of B. The main difference between the embodiments of FIG. 5, FIG. 6 and FIG. 7 is the number of repeating AB units. In each case the first reactive gas and the last reactive gas in the gas injector unit is a first reactive gas A injector. Adding additional AB units may serve to increase the throughput with only a relatively small change in the complexity of the design.

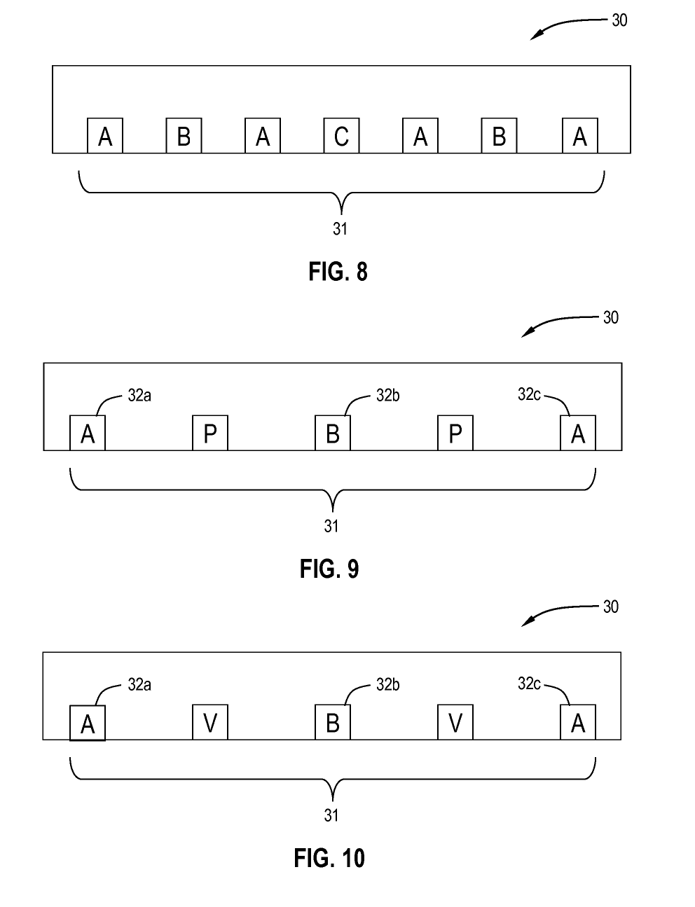

FIG. 8 shows another embodiment of the invention in which the plurality of gas injectors 32 further comprise at least one third gas injector for a third reactive gas C. At least two first reactive gas A injectors surround the at least one third gas reactive gas injector. A substrate moved back and forth across this gas injector unit 31 would see a pulse sequence of
AB AC AB AAB AC AB (AAB AC AB)ₙ . . . AAB AC ABA
   resulting in a film composition of BCB(BCB)ₙ . . . BCB. Again, the final exposure to the first reactive gas A is not important.

FIG. 9 shows another embodiment of the invention in which the at least one gas injector unit further comprises at least two purge gas P injectors. Each of the purge gas P injectors is between the at least one first reactive gas A injector and the at least one second reactive gas B injector. A substrate exposed to this sequence would have the same film formation as that of FIG. 5, as the purge gas P does not react with either the first reactive gas A or the second reactive gas B. Use of the purge gas P may be particularly helpful in that it can help keep the first reactive gas A and the second reactive gas B from reacting adjacent the surface of the substrate, rather than sequentially on/with the surface of the substrate.

In specific embodiments, the gas injector unit 31 consists essentially of, in order, a leading first reactive gas A injector 32a, a second reactive gas B injector 32b and a trailing first reactive gas A injector 32c. As used in this specification and the appended claims, the term “consisting essentially of”, and the like, mean that the gas injector unit 31 excludes additional reactive gas injectors, but does not exclude non-reactive gas injectors like purge gases and vacuum lines. Therefore, in the embodiment shown in FIG. 5, the addition of purge gases (see e.g., FIG. 9) would still consist essentially of ABA, while the addition of a third reactive gas C injector (see e.g., FIG. 8) would not consist essentially of ABA. FIG. 10 is the same configuration as that of FIG. 9 with the purge gas P injectors being substituted with vacuum ports P.

FIG. 11 shows a further embodiment of the invention in which the plurality of gas injectors 32 further comprises four second reactive gas B injectors and one third reactive gas C injector. Each of the second reactive gas B injectors and third reactive gas C injector are separated by first reactive gas A injectors. The injector configuration shown here is ABABACABABA. A substrate moved back and forth across this gas injector unit 31 would see a pulse sequence of
AB AB AC AB AB (AAB AB AC AB AB)ₙ . . . AAB AB AC AB ABA
   resulting in a film composition of BBC(BBBB)ₙ . . . CBB. Again, the final exposure to the first reactive gas A is not important.

FIG. 12 shows an embodiment included additional gas injectors 32 in which the gas injector unit 31 consists essentially of the ABA configuration. In this embodiment, a purge gas P injector 32d is between the leading first reactive gas A injector 32a and the second reactive gas B injector 32b. A purge gas P injector 32e is between the second reactive gas B injector 32b and the trailing first reactive gas A injector 32c. Each of the purge gas P injectors are separated from the reactive gas injectors by a vacuum port V. As in the embodiment of FIG. 5, a substrate exposed to this configuration would result in a uniform formation of film B. More detailed embodiments, further comprise, in order, a vacuum port V, a purge gas P injector and another vacuum port P before the leading first reactive gas A injector 32a and after the trailing first reactive gas A injector 32c.

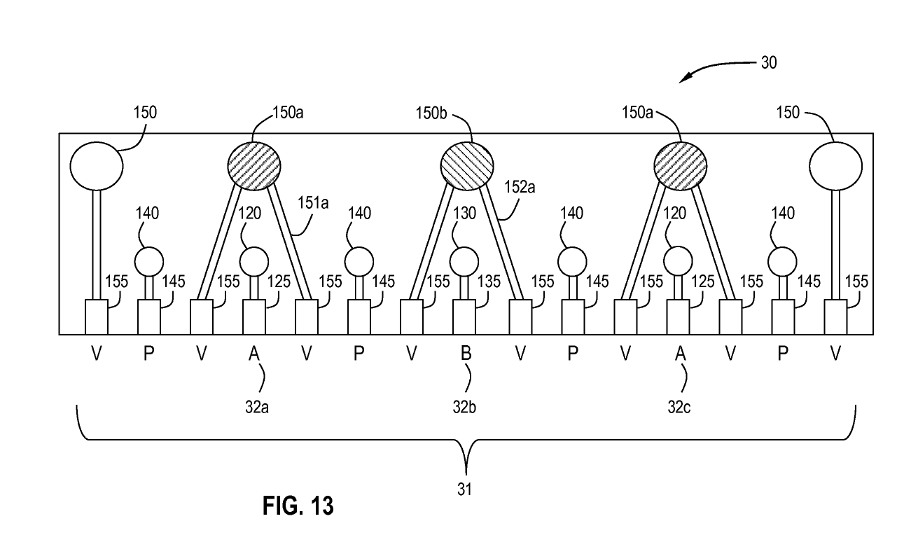

FIG. 13 shows a detailed embodiment of the gas distribution plate 30. As shown here, the gas distribution plate 30 comprises a single gas injector unit 31 which may include the outside purge gas P injectors and outside vacuum V ports. In the detailed embodiment shown, the gas distribution plate 30 comprises at least two pumping plenums connected to the pumping system 150. The first pumping plenum 150a is in flow communication with the vacuum ports 155 adjacent to (on either side of) the gas ports 125 associated with the first reactive gas A injectors 32a, 32c. The first pumping plenum 150a is connected to the vacuum ports 155 through two vacuum channels 151a. The second pumping plenum 150b is in flow communication with the vacuum ports 155 adjacent to (on either side of) the gas port 135 associated with the second reactive gas B injector 32b. The second pumping plenum 150b is connected to the vacuum ports 155 through two vacuum channels 152a. In this manner, the first reactive gas A and the second reactive gas B are substantially prevented from reacting in the gas phase. The vacuum channels in flow communication with the end vacuum ports 155 can be either the first vacuum channel 150a or the second vacuum channel 150b, or a third vacuum channel. The pumping plenums 150, 150a, 150b can have any suitable dimensions. The vacuum channels 151a, 152a can be any suitable dimension. In specific embodiments, the vacuum channels 151a, 152a have a diameter of about 22 mm. The end vacuum plenums 150 collect substantially only purge gases. An additional vacuum line collects gases from within the chamber. These four exhausts (A, B, purge gas and chamber) can be exhausted separately or combined downstream to one or more pumps, or in any combination with two separate pumps.

A specific embodiment of the invention is directed to an atomic layer deposition system comprising a processing chamber with a gas distribution plate therein. The gas distribution plate comprises a plurality of gas injectors consisting essentially of, in order, a vacuum port, a purge gas injector, a vacuum port, a first reactive gas injector, a vacuum port, a purge port, a vacuum port, a second reactive gas injector, a vacuum port, a purge port, a vacuum port, a first reactive gas injector, a vacuum port, a purge port and a vacuum port.

In some embodiments, the gas plenums and gas injectors may be connected with a purge gas supply (e.g., nitrogen). This allows the plenums and gas injectors to be purged of residual gases so that the gas configuration can be switched, allowing the B gas to flow from the A plenum and injectors, and vice versa. Additionally, the gas distribution plate 30 may include additional vacuum ports along sides or edges to help control unwanted gas leakage. As the pressure under the injector is about 1 torr greater than the chamber, the additional vacuum ports may help prevent reactive gases leaking into the chamber. In some embodiments, the gas distribution plate 30 also includes one or more heater or cooler.

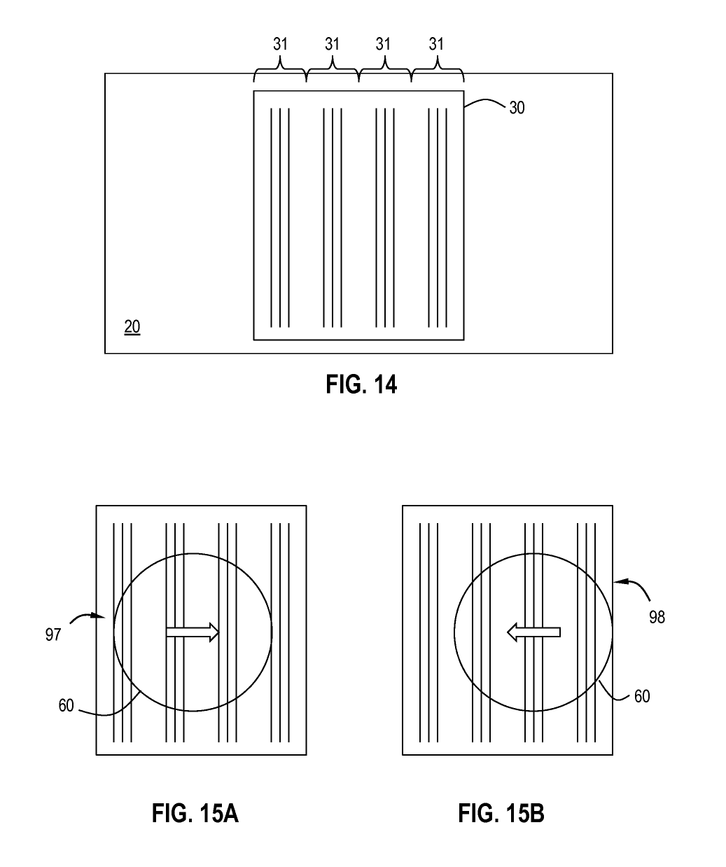

Additional embodiments of the invention are directed to atomic layer deposition systems comprising a gas distribution plate 30 having more than one gas injector unit 31. FIG. 14 shows a processing chamber 20 with a gas distribution plate 30 located therein. The gas distribution plate 30 is shown with four individual gas injector units 31, each represented by three parallel lines. Although four gas injector units 31 are shown, there can be any number of gas injector units, depending on the desired processing. In detailed embodiments, there are in the range of about 2 to about 24 gas injector units.

In one embodiment, each individual gas injector units 31 has a sequence of gas injectors in the ABA configuration. In specific embodiments, each of the gas injector units 31 consists essentially of, in order, a leading first reactive gas A injector, a second reactive gas B injector, and a trailing first reactive gas A injector.

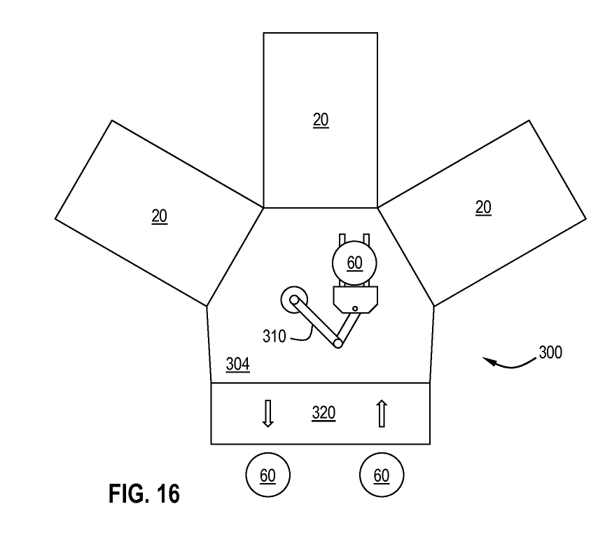

In a system such as that shown in FIG. 14, the substrate does not need to travel the entire length of the gas distribution plate 30 to completely process a layer. This may be referred to as a short stroke process, short-stroke atomic layer deposition (SS-ALD) or other similar names. To process the substrate using the arrangement of FIG. 13, the substrate 60 would need to move from a first extent 97 to a second extent 98. The first extent 97 being a starting point and the second extent 98 being an ending point for the short-stroke movement. FIG. 15A shows a substrate 60 at the first extent 97, for this embodiment. The substrate 60 in FIG. 15A is moving from left-to-right. FIG. 15B shows the substrate at the second extent 98, for this embodiment. The substrate has moved far enough so that every part of the substrate has been exposed to one of the gas injector units. Each portion of the substrate is deposited with a strip of film and the length of the stroke is sufficient to connect these strips into a continuous film.

A full stroke (back and forth paths) would result in a full cycle (2 layer) exposure to the substrate. In this short-stroke configuration, the substrate carrier can be configured to move, during processing, in a linear reciprocal path between the first extent and second extent. The substrate 60 is always under the gas distribution plate during processing. The distance between the first extent 97 and the second extent 98 is about equal to a length of the substrate divided by the number of gas injector units. So in the embodiment shown in FIGS. 15A and 15B, the substrate has moved about ¼ of its total length. For a 300 mm substrate, that would be about a 75 mm distance. For gas distribution plates 30 with larger numbers of gas injector units 31, the distance of travel is proportionately less. In certain embodiments, rotational movement may also be employed after every stroke, or after multiple strokes. The rotational movement may be discrete movements, for example 10, 20, 30, 40, or 50 degree movements or other suitable incremental rotational movement. Such rotational movement together with linear movement may provide more uniform film formation on the substrate.

In detailed embodiments, the substrate carrier is configured to carry the substrate outside of the first extent 97 to a loading position. In some embodiments, the substrate carrier is configured to carry the substrate outside of the second extent 98 to an unloading position. The loading and unloading positions can be reversed if necessary.

Additional embodiments of the invention are directed to methods of processing a substrate. A portion of a substrate is passed across a gas injector unit in a first direction. As used in this specification and the appended claims, the term “passed across” means that the substrate has been moved over, under, etc., the gas distribution plate so that gases from the gas distribution plate can react with the substrate or layer on the substrate. In moving the substrate in the first direction, the substrate is exposed to, in order, a leading first reactive gas stream, a second reactive gas stream and a trailing first reactive gas stream to deposit a first layer. The portion of the substrate is then passed across the gas injector unit in a direction opposite of the first direction so that the portion of the substrate is exposed to, in order, the trailing first reactive gas stream, the second reactive gas stream and the leading first reactive gas stream to create a second layer. If there is only one gas injector unit, the substrate will be passed beneath the entire relevant portion of the gas distribution plate. Regions of the gas distribution plate outside of the reactive gas injectors is not part of the relevant portion. In embodiments where there is more than one gas injector unit, the substrate will move a portion of the length of the substrate based on the number of gas injector units. Therefore, for every n gas injector units, the substrate will move 1/nth of the total length of the substrate.

In detailed embodiments, the method further comprises exposing the portion of the substrate to a purge gas stream between each of the first reactive gas streams and the second reactive gas streams. The gases of some embodiments are flowing continuously. In some embodiments, the gases are pulsed as the substrate moves beneath the gas distribution plate.

According to one or more embodiments, passing the portion of the substrate in a first direction exposes the portion of the substrate to, in order, a leading first reactive gas stream, a leading second reactive gas stream, a first intermediate first reactive gas stream, a third reactive gas stream, a second intermediate first reactive gas stream, a trailing second reactive gas stream and a trailing first reactive gas stream, and passing the portion of the substrate in the second direction exposes the portion of the substrate to the gas streams in reverse order.

Additional embodiments of the invention are directed to cluster tools comprising at least one atomic layer deposition system described. The cluster tool has a central portion with one or more branches extending therefrom. The branches being deposition, or processing, apparatuses. Cluster tools which incorporate the short stroke motion require substantially less space than tools with conventional deposition chambers. The central portion of the cluster tool may include at least one robot arm capable of moving substrates from a load lock chamber into the processing chamber and back to the load lock chamber after processing. Referring to FIG. 16, an illustrative cluster tool 300 includes a central transfer chamber 304 generally including a multi-substrate robot 310 adapted to transfer a plurality of substrates in and out of the load lock chamber 320 and the various process chambers 20. Although the cluster tool 300 is shown with three processing chambers 20, it will be understood by those skilled in the art that there can be more or less than 3 processing chambers. Additionally, the processing chambers can be for different types (e.g., ALD, CVD, PVD) of substrate processing techniques.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

1. An atomic layer deposition system for processing a substrate, comprising:
a processing chamber;
a reciprocating substrate carrier inside the processing chamber; and
a set of gas injectors inside the processing chamber and adjacent the reciprocating substrate carrier, the set of gas injectors including a first reactive gas injector, a second reactive gas injector and a third reactive gas injector, the first reactive gas injector and the second reactive gas injector in fluid communication with a first reactive gas A to inject gas A into the processing chamber toward the substrate carrier and the third reactive gas injector in fluid communication with a second reactive gas B to inject gas B into the processing chamber toward the substrate carrier;
wherein the reciprocating substrate carrier carries the substrate in a first direction under each of the reactive gas injectors to expose the substrate to gases in the order ABA and wherein the reciprocating substrate carrier carries the substrate in a second direction under each of the reactive gas injectors to expose the substrate to gases in the order ABA.

2. The atomic layer deposition system of claim 1, the set of gas injectors further including a fourth and a fifth reactive gas injector, the fourth reactive gas injector in fluid communication with the first reactive gas A to inject gas A into the processing chamber toward the substrate carrier and the fifth reactive gas injectors in fluid communication with the second reactive gas B to inject gas B into the processing chamber toward the substrate carrier;
wherein the reciprocating substrate carrier carries the substrate in a first direction under each of the reactive gas injectors to expose the substrate to gases in the order ABABA and wherein the reciprocating substrate carrier carries the substrate in a second direction under each of the reactive gas injectors to expose the substrate to gases in the order ABABA.

3. The atomic layer deposition system of claim 1, the set of gas injectors comprising a first purge gas injector located between the first reactive gas injector and the second reactive gas injector and a second purge gas injector located between the second reactive gas injector and the third reactive gas injector.

4. The atomic layer deposition system of claim 1, the set of gas injectors comprising a first vacuum gas injector located between the first reactive gas injector and the second reactive gas injector and a second vacuum gas injector located between the second reactive gas injector and the third reactive gas injector.

5. The atomic layer deposition system of claim 3, the set of gas injectors comprising a first vacuum gas injector and a second vacuum gas injector located on either side of the first purge gas injector and a third vacuum gas injector and a fourth vacuum gas injector located between the first reactive gas injector and the second reactive gas injector and a second purge gas injector located between the second reactive gas injector and the third reactive gas injector.

6. The atomic layer deposition system of claim 1, comprising n additional sets of gas injectors located inside the processing chamber and adjacent the reciprocating substrate carrier, each of the n additional sets of gas injectors including a fourth reactive gas injector, a fifth reactive gas injector and a sixth reactive gas injector, the fourth reactive gas injectors and the fifth reactive gas injectors in fluid communication with the first reactive gas A to inject gas A into the processing chamber toward the substrate carrier and the sixth reactive gas injectors in fluid communication with the second reactive gas B to inject gas B into the processing chamber toward the substrate carrier;
wherein the reciprocating substrate carrier carries the substrate in a first direction under each of the reactive gas injectors to expose the substrate to gases in the order ABAABA and wherein the reciprocating substrate carrier carries the substrate in a second direction under the each of the reactive gas injectors to expose the substrate to gases in the order ABAABA.

7. The atomic layer deposition of claim 6, wherein each of the sets of gas injectors includes a first vacuum gas injector, a first purge gas injector and a second vacuum gas injector located in between each of the reactive gas injectors.

8. The atomic layer deposition system of claim 1, wherein the reciprocating substrate iteratively moves in the first direction and then in the second direction.

9. The atomic layer deposition system of claim 1, wherein the substrate carrier rotates the substrate as the substrate carrier carries the substrate under the first reactive gas injector, the second reactive gas injector and the third reactive gas injector.

10. The atomic layer deposition system of claim 9, wherein the substrate carrier rotates the substrate at an incremental angle.

11. The atomic layer deposition system of claim 1, comprising one or more additional processing chambers each containing a reciprocating substrate carrier and another set of gas injectors adjacent the reciprocating substrate carrier, the set of gas injectors in the one or more additional processing chambers each including a first reactive gas injector, a second reactive gas injector and a third reactive gas injector, the first reactive gas injector and the second reactive gas injector in fluid communication with a first reactive gas A to inject gas A into the processing chamber toward the substrate carrier and the third reactive gas injector in fluid communication with a second reactive gas B to inject gas B into the processing chamber toward the substrate carrier;
wherein the reciprocating substrate carrier in each of the one or more additional processing chambers carries the substrate in a first direction under each of the reactive gas injectors to expose the substrate to gases in the order ABA and wherein the reciprocating substrate carrier carries the substrate in a second direction under each of the reactive gas injectors to expose the substrate to gases in the order ABA.

12. An atomic layer deposition system for processing a substrate, comprising:
a processing chamber;
a reciprocating substrate carrier inside the processing chamber; and
a set of gas injectors inside the processing chamber and adjacent the reciprocating substrate carrier, the set of gas injectors including one or more first reactive gas injectors in fluid communication with a first reactive gas A to inject gas A into the processing chamber, one or more second reactive gas injector in fluid communication with a second reactive gas B to inject gas B into the processing chamber and a third reactive gas injector in fluid communication with a third reactive gas C to inject gas C into the processing chamber;
wherein the reciprocating substrate carrier carries the substrate in a first direction under each of the reactive gas injectors exposing the substrate to gases A, B and C at different times and wherein the reciprocating substrate carrier carries the substrate in a second direction under each of the reactive gas injectors exposing the substrate to gases A, B and C.

13. The atomic layer deposition system of claim 12, wherein the at least one first reactive gas injectors, the at least one second reactive gas injector and the third reactive gas injectors are arranged relative to the reciprocating substrate carrier so that when the reciprocating substrate carrier carries the substrate in a first direction under each of the reactive gas injectors exposing the substrate to gases in the order ABACABA and wherein the reciprocating substrate carrier carries the substrate in a second direction under each of the reactive gas injectors exposing the substrate to gases in the order ABACABA.

14. The atomic layer deposition system of claim 12, comprising a purge gas injector located between each reactive gas injector.

15. The atomic layer deposition system of claim 12, comprising a vacuum gas injector located between each reactive gas injector.

16. The atomic layer deposition system of claim 14, comprising two vacuum gas injectors located between each reactive gas injector.

17. A method of processing a substrate in a processing chamber having a first reactive gas injector, a second reactive gas injector, a third reactive gas injector and a reciprocating substrate carrier that carries the substrate, comprising:
moving the substrate on a reciprocating substrate carrier in a first direction under the first reactive gas injector that injects gas A onto the substrate;
moving the substrate on a reciprocating substrate carrier in the first direction under the second reactive gas injector that injects gas B onto the substrate; and
moving the substrate on a reciprocating substrate carrier in the first direction under the third reactive gas injector that injects gas A onto the substrate.

18. The method of claim 17, comprising:
moving the substrate on a reciprocating substrate carrier in a second direction that is opposite the first direction under the third reactive gas injector that injects gas A onto the substrate;
moving the substrate on a reciprocating substrate carrier in the second direction under the second reactive gas injector that injects gas B onto the substrate; and
moving the substrate on a reciprocating substrate carrier in the second direction under the first reactive gas injector that injects gas A onto the substrate.

19. The method of claim 18, further comprising exposing the substrate to a purge gas stream between each step of claims 17 and 18.

20. The method of claim 18, further comprising exposing the substrate to a vacuum between each step of claims 17 and 18.
